(19) United States
(12) Patent Application Publication
(10) Pub. No.: US 2025/0112201 A1
(43) Pub. Date: Apr. 3, 2025

(54) BONDING SYSTEMS, AND METHODS OF BONDING A SEMICONDUCTOR ELEMENT TO A SUBSTRATE

(71) Applicant: Kulicke and Soffa Industries, Inc., Fort Washington, PA (US)

(72) Inventors: Andreas Marte, Berg (CH); James E. Eder, Doylestown, PA (US); Michael P. Schmidt-Lange, North Wales, PA (US)

(73) Assignee: Kulicke and Soffa Industries, Inc., Fort Washington, PA (US)

(21) Appl. No.: 18/825,456

(22) Filed: Sep. 5, 2024

Related U.S. Application Data
(60) Provisional application No. 63/541,888, filed on Oct. 1, 2023.

(51) Int. Cl. H01L 23/00; H01L 23/544

(52) U.S. Cl. CPC H01L 24/81; H01L 23/544; H01L 24/75; H01L 2223/54426; H01L 2224/75753; H01L 2224/8113; H01L 2224/81203

(57) ABSTRACT

A bonding system for bonding a semiconductor element to a substrate is provided. The bonding system includes a bonding tool configured for bonding the semiconductor element to the substrate. The bonding tool is configured to carry the semiconductor element with at least one fiducial marking on the semiconductor element facing the bonding tool. The bonding system also includes an imaging system for imaging the at least one fiducial marking from a position beneath the semiconductor element while the semiconductor element is being carried by the bonding tool.

### CROSS-REFERENCE TO RELATED APPLICATION

This application claims the benefit of U.S. Provisional Application No. 63/541,888, filed Oct. 1, 2023, the content of which is incorporated herein by reference.

### FIELD

The invention relates to systems and methods for bonding a semiconductor element to a substrate, and in particular, to improved imaging and alignment operations used in connection with the bonding of the semiconductor element to the substrate.

### SUMMARY

According to an exemplary embodiment of the invention, a bonding system for bonding a semiconductor element to a substrate is provided. The bonding system includes a bonding tool configured for bonding the semiconductor element to the substrate. The bonding tool is configured to carry the semiconductor element with at least one fiducial marking on the semiconductor element facing the bonding tool. The bonding system also includes an imaging system for imaging the at least one fiducial marking from a position beneath the semiconductor element while the semiconductor element is being carried by the bonding tool.

According to other embodiments of the invention, the bonding system recited in the immediately preceding paragraph may have any one or more of the following features: the bonding system is a thermocompression bonding system; the imaging system is configured to use light having an infrared wavelength in connection with the imaging of the at least one fiducial marking on the semiconductor element; further including a support structure configured for supporting the substrate with at least one fiducial marking on an upper surface of the substrate; the imaging system is configured to use visible light in connection with imaging of the at least one fiducial marking on the substrate; further including a support structure configured for supporting the substrate with at least one fiducial marking on an upper surface of the substrate, the imaging system is configured to use light having an infrared wavelength in connection with the imaging of the at least one fiducial marking on the semiconductor element, and the imaging system is configured to use visible light in connection with imaging of the at least one fiducial marking on the substrate; the imaging system is a look up/down imaging system, the imaging system utilizing a look up imaging path for imaging the at least one fiducial marking on the semiconductor element, the imaging system utilizing a look down imaging path for imaging the at least one fiducial marking on the substrate; further including a support structure configured for supporting the substrate with a plurality of fiducial markings on an upper surface of the substrate, the at least one fiducial marking on the semiconductor element includes a plurality of fiducial markings on the semiconductor element, the imaging system is configured to image one of the fiducial markings on the upper surface of the substrate simultaneously with imaging of one of the fiducial markings on the semiconductor element; the bonding system is configured to align the semiconductor element with the substrate after imaging of the at least one fiducial marking on the semiconductor element; and/or further including a support structure configured for supporting the substrate with at least one fiducial marking on an upper surface of the substrate, the imaging system being configured to image the at least one fiducial marking on the upper surface of the substrate, the bonding system is configured to align the semiconductor element with the substrate after imaging of (i) the at least one fiducial marking on the semiconductor element and (ii) the at least one fiducial marking on the upper surface of the substrate.

According to another exemplary embodiment of the invention, a method of bonding a semiconductor element to a substrate is provided. The method includes the steps of: (a) carrying the semiconductor element with a bonding tool with at least one fiducial marking on the semiconductor element facing the bonding tool; (b) imaging the at least one fiducial marking with an imaging system from a position beneath the semiconductor element while the semiconductor element is being carried by the bonding tool; and (c) bonding the semiconductor element to the substrate.

According to other embodiments of the invention, the method of bonding a semiconductor element to a substrate recited in the immediately preceding paragraph may have any one or more of the following features: step (c) includes thermocompressively bonding the semiconductor element to the substrate; step (b) includes using light having an infrared wavelength in connection with the imaging of the at least one fiducial marking on the semiconductor element; further including a step of supporting the substrate with a support structure, the support structure being configured to support the substrate with at least one fiducial marking on an upper surface of the substrate; further including a step of using visible light in connection with imaging of the at least one fiducial marking on the substrate; further including a step of supporting the substrate with a support structure, the support structure being configured to support the substrate with at least one fiducial marking on an upper surface of the substrate, step (b) includes using light having an infrared wavelength in connection with the imaging of the at least one fiducial marking on the semiconductor element, further including a step of using visible light from the imaging system in connection with imaging of the at least one fiducial marking on the substrate; the imaging system is a look up/down imaging system, the imaging system utilizing a look up imaging path for imaging the at least one fiducial marking on the semiconductor element, the imaging system utilizing a look down imaging path for imaging the at least one fiducial marking on the substrate; further including a step of supporting the substrate with a support structure, the support structure being configured to support the substrate with a plurality of fiducial markings on an upper surface of the substrate, the at least one fiducial marking on the semiconductor element includes a plurality of fiducial markings on the semiconductor element, step (b) includes using the imaging system to image one of the fiducial markings on the upper surface of the substrate simultaneously with imaging of one of the fiducial markings on the semiconductor element; further including a step of aligning the semiconductor element with the substrate after step (b); and/or further including a step of supporting the substrate with a support structure, the support structure being configured to support the substrate with at least one fiducial marking on an upper surface of the substrate, further including a step of imaging the at least one fiducial marking on the upper surface of the substrate with the imaging system, further including a step of aligning the semiconductor element with the substrate before step (c), after step (b), and after the step of imaging the at least one fiducial marking on the upper surface of the substrate with the imaging system.

### BRIEF DESCRIPTION OF THE DRAWINGS

The invention is best understood from the following detailed description when read in connection with the accompanying drawings. It is emphasized that, according to common practice, the various features of the drawings are not to scale. On the contrary, the dimensions of the various features are arbitrarily expanded or reduced for clarity. Throughout the drawings, like reference numerals indicate like elements, except where expressly set forth herein. Included in the drawings are the following figures:

FIG. 1A is a block diagram side view of a semiconductor element configured to be bonded to a substrate in accordance with an exemplary embodiment of the invention;

FIG. 1B is a block diagram top view of the semiconductor element and the substrate of FIG. 1A after bonding;

FIGS. 2A-2F are a series of block diagram side views illustrating a method of bonding a semiconductor element to a substrate in accordance with an exemplary embodiment of the invention; and

FIGS. 3A-3D are a series of block diagram side views illustrating another method of bonding a semiconductor element to a substrate in accordance with an exemplary embodiment of the invention.

### DETAILED DESCRIPTION

As used herein, the term “semiconductor element” is intended to refer to any structure including (or configured to include at a later step) a semiconductor chip or die. Exemplary semiconductor elements include a bare semiconductor die, a semiconductor die on a substrate (e.g., a leadframe, a PCB, a carrier, a semicondutor wafer, a BGA substrate, etc.), a packaged semiconductor device, a flip chip semiconductor device, a die embedded in a substrate, a stack of semiconductor die, amongst others. Further, the semiconductor element may include an element configured to be bonded or otherwise included in a semiconductor package (e.g., a spacer to be bonded in a stacked die configuration, a substrate, etc.).

As used herein, the term “substrate” is intended to refer to any structure to which an electronic component (e.g., a semiconductor element) may be bonded (e.g., thermocompressively bonded, ultrasonically bonded, thermosonically bonded, die bonded, etc.). Exemplary substrates include, for example, a leadframe, a PCB, a carrier, a semiconductor wafer, a BGA substrate, a semiconductor element, etc.

Aspects of the invention relate to enabling accurate placement (and/or bonding) of a semiconductor element (e.g., a semiconductor die) on a target substrate by aligning fiducials on the semiconductor element and fiducials on the target substrate. For example, alignment fiducials on the semiconductor element are on the “top side” which does not come in contact with the target substrate after placement.

Exemplary aspects of the invention allow for a direct alignment of top side fiducials of a semiconductor element using an imaging system (e.g., an optical system) which includes a plurality of selectable illumination wavelengths. At least one of the wavelengths may be within the infrared spectral band and may have a value greater than 750 nm (e.g., greater than 1000 nm) so that the illumination can look through the semiconductor element to detect the top side fiducials while looking from the bottom.

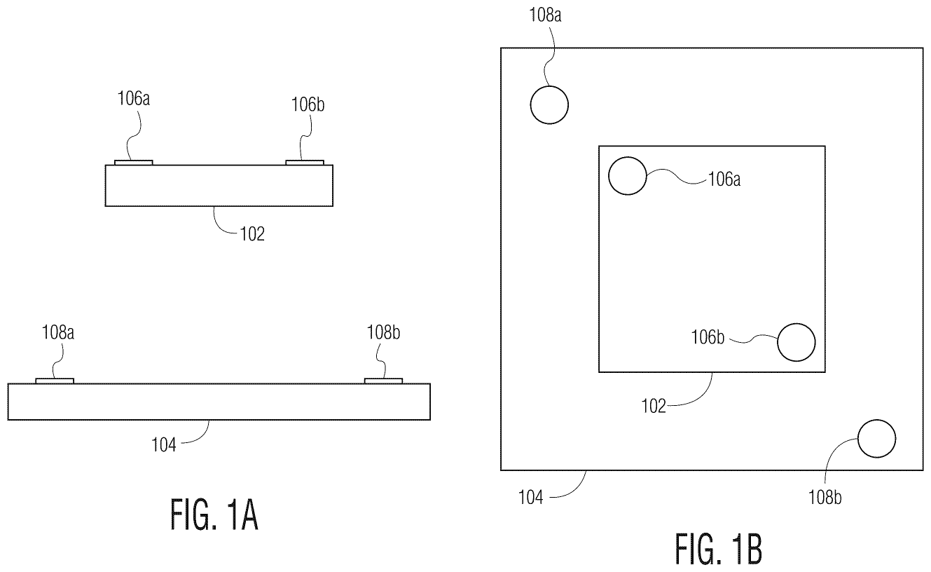

FIG. 1A illustrates a semiconductor element 102 (e.g., a semiconductor die) configured to be bonded to a substrate 104. For example, semiconductor element 102 may be configured to be thermocompressively bonded to substrate 104. It shall be understood that each of semiconductor element 102 and substrate 104 are shown in a simplified configuration. For example, semiconductor element 102 may include conductive structures configured to be bonded (e.g., using heat and force) to conductive structures of substrate 104.

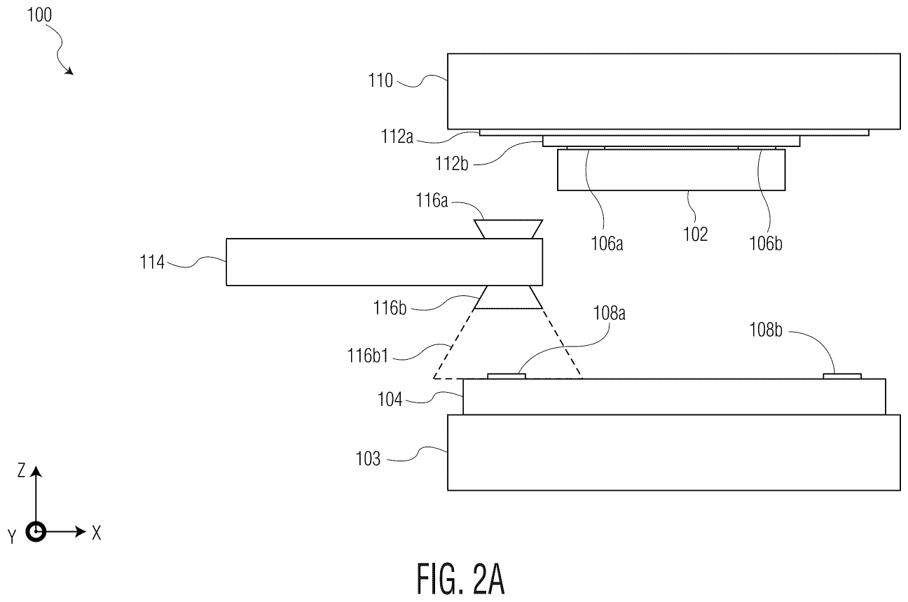

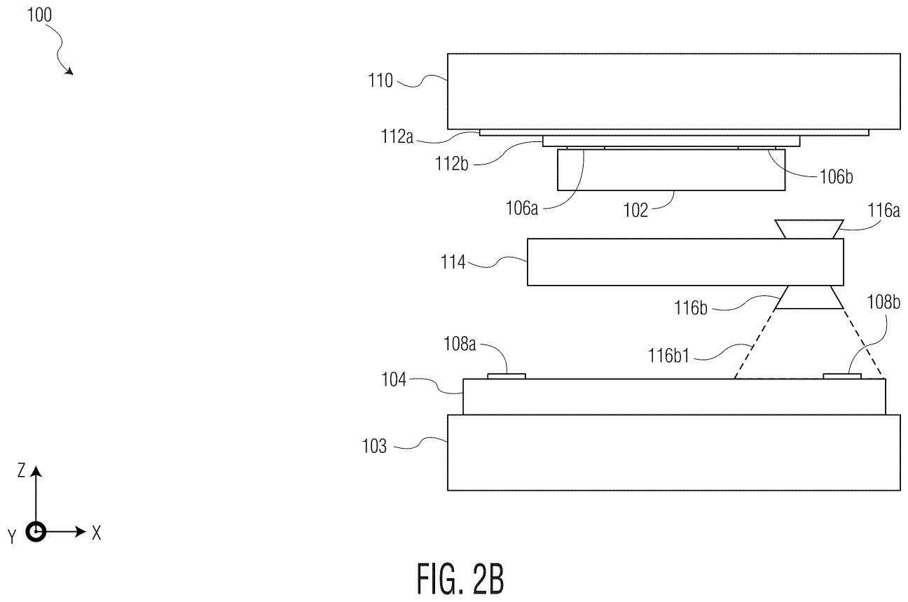

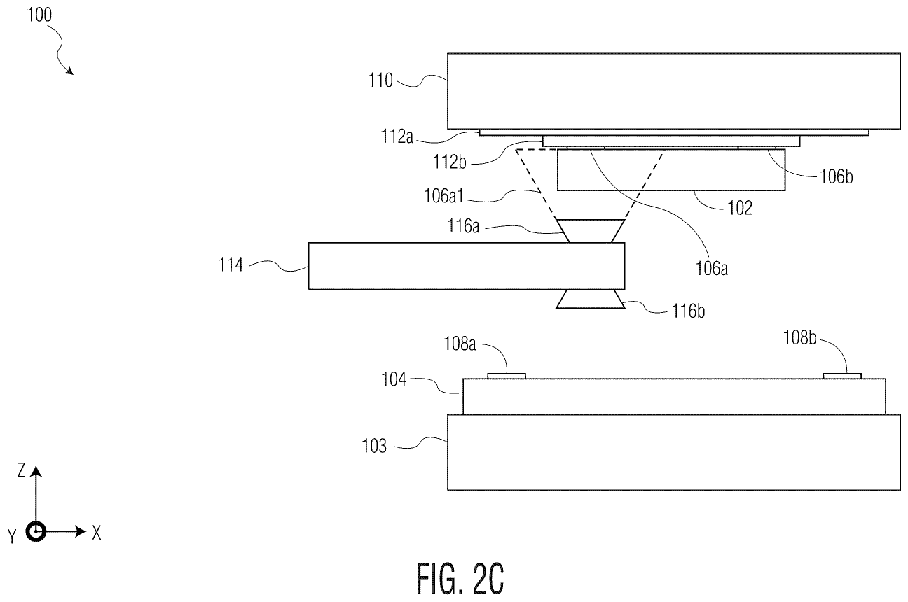

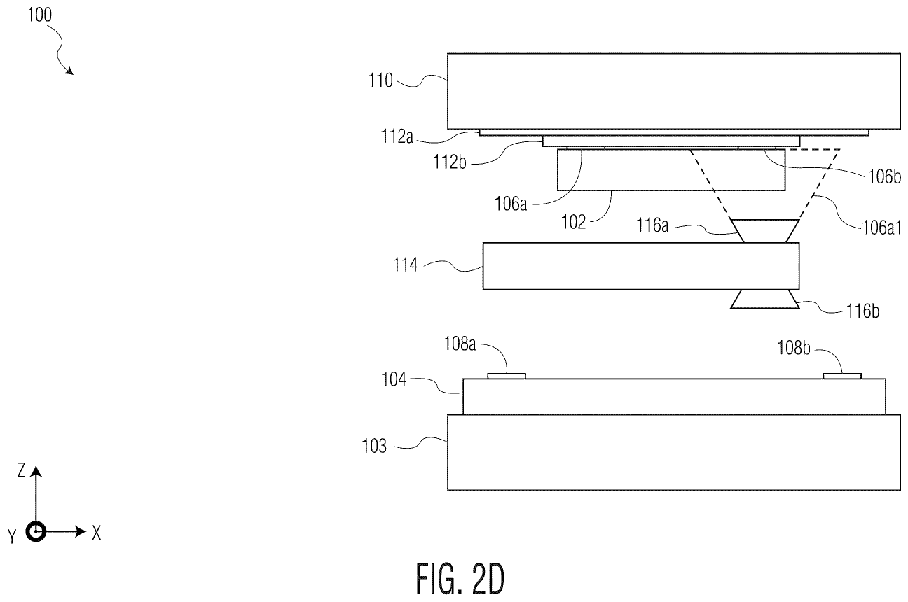

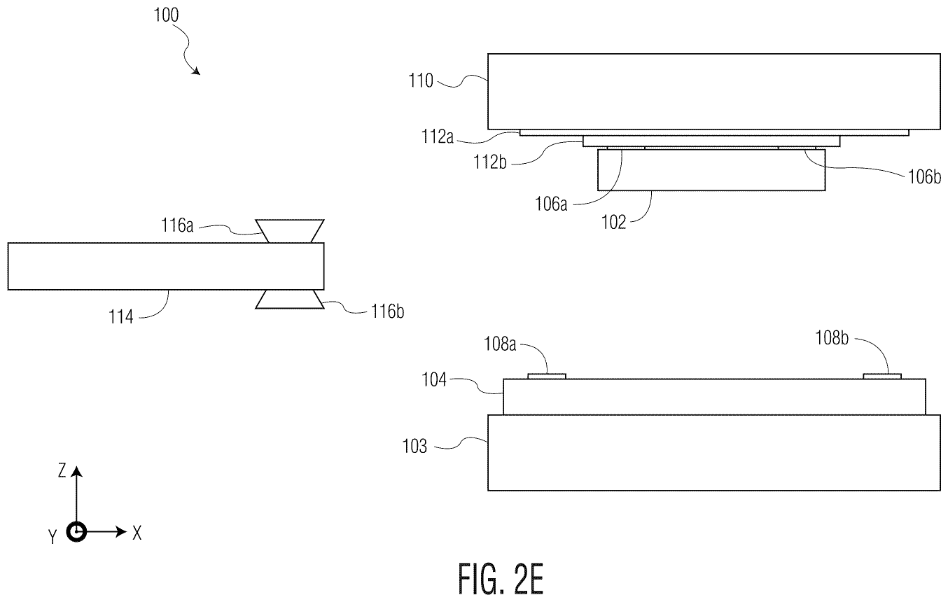

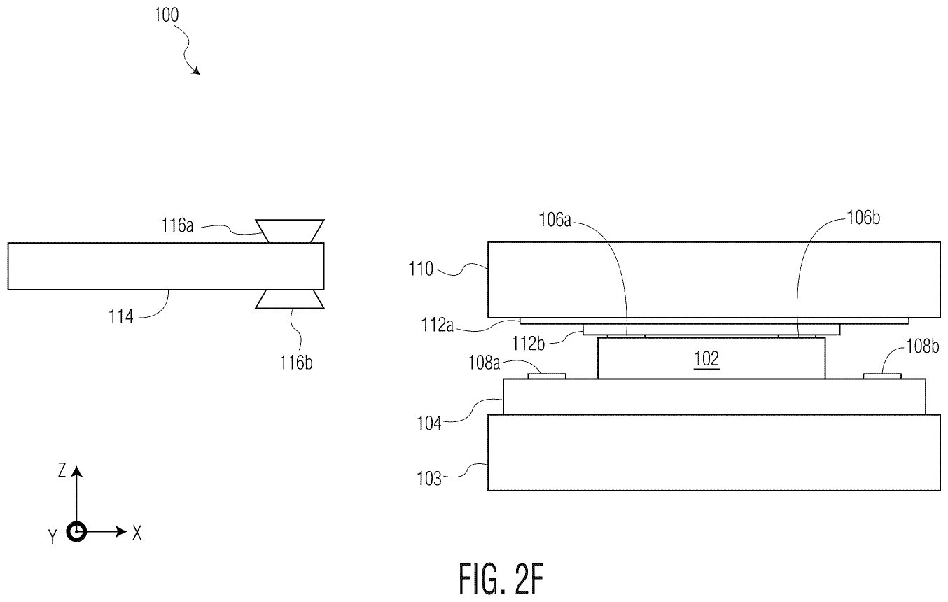

In order to properly bond semiconductor element 102 to substrate 104, it is important to properly align semiconductor element 102 with substrate 104 prior to bonding. Semiconductor element 102 includes fiducial markings 106a and 106b. Substrate 104 includes fiducial markings 108a and 108b. In order to properly align semiconductor element 102 with substrate 104 prior to bonding, it is useful to image fiducial markings 106a and 106b, and fiducial markings 108a and 108b. By imaging these fiducial markings with an imaging system 114 (e.g., see imaging system 114 of FIG. 2A), the relative position of semiconductor element 102 and substrate 104 is known, so that adjustments may be made during (and/or after) alignment, and/or prior to placement and bonding.

FIG. 1B illustrates semiconductor element 102 bonded to substrate 104. As can be seen in FIGS. 1A-1B, fiducial markings 106a and 106b are on a top side (e.g., a top surface) of semiconductor element 102. Thus, fiducial markings 106a and 106b cannot easily be imaged by a camera while semiconductor element 102 is held by a bonding tool.

FIG. 2A illustrates bonding system 100 (e.g., a thermocompression bonder). Bonding system 100 includes a bond head assembly 110. Bond head assembly 110 includes a heater 112a and a bonding tool 112b. In certain bonding systems or machines (e.g., thermocompression bonding machines) it may be desirable to heat the bonding tool. Thus, while FIG. 2A (and certain other drawings herein) illustrates a separate heater 112a for heating bonding tool 112b for heating semiconductor element 102 (e.g., including a plurality of electrically conductive structures of semiconductor element 102), it will be appreciated that heater 112a and bonding tool 112b may be integrated into a single element (e.g., a heated bonding tool).

Bonding tool 112b is illustrated carrying semiconductor element 102 including fiducial markings 106a and 106b. Bonding system 100 also includes a support structure 103 configured for supporting substrate 104. Substrate 104 includes fiducial markings 108a and 108b on an upper surface of substrate 104. Bonding system 100 also includes imaging system 114 (e.g., a camera system, such as a look up/down imaging system). With bonding tool 112b in the illustrated position above substrate 104 (shown in FIG. 2A), imaging system 114 has been moved into a position such that imaging operations may be completed with respect to fiducial markings 106a and 106b on the semiconductor element 102, and imaging fiducial markings 108a and 108b on substrate 104.

Imaging system 114 includes a look up imaging path 116a for imaging fiducial markings 106a and 106b on the semiconductor element 102. Imaging system 114 also includes a look down imaging path 116b for imaging fiducial markings 108a and 108b on substrate 104. FIGS. 2A-2B illustrate imaging system 114 using visible light 116b1 (from look down imaging path 116b) in connection with imaging of fiducial markings 108a and 108b on substrate 104. After the imaging of fiducial markings 108a and 108b (in FIGS. 2A-2B), FIGS. 2C-2D illustrate imaging system 114 using light having an infrared wavelength 116a1 (from look up imaging path 116a) in connection with imaging of fiducial markings 106a and 106b on semiconductor element 102. That is, because infrared light (or another light being able to image through semiconductor element 102) is used, fiducial markings 106a and 106b may be imaged by imaging system 114 from a position beneath semiconductor element 102 while semiconductor element 102 is being carried by bonding tool 112b. In order to clearly image fiducial markings 106a and 106b from below (as shown in FIGS. 2C-2D), it is desirable that semiconductor element 102 does not include certain circuitry below fiducial markings 106a and 106b that could block the imaging using imaging path 116a. For example, it may be desirable that semiconductor element 102 is transparent to infrared light at the portion of semiconductor element 102 below fiducial markings 106a and 106b.

After the imaging operations are completed (e.g., imaging operations with respect to fiducial markings 106a and 106b on the semiconductor element 102, and with respect to fiducial markings 108a and 108b on substrate 104), imaging system 114 is moved as shown in FIG. 2E, such that there is a clear path for bonding tool 112b to bond semiconductor element 102 to substrate 104. With data from the imaging operations of imaging system 114, calculations are completed for corrections to be made to properly align semiconductor element 102 with substrate 104 (e.g., corrections along the x-axis, corrections along the y-axis, corrections about the z-axis, etc.). Using these corrections, semiconductor element 102 is then properly aligned with substrate 104 (e.g., through motion of bond head assembly 110 and/or support structure 103). Then, after the alignment is completed, semiconductor element 102 is bonded (e.g., thermocompressively bonded) to substrate 104 at FIG. 2F.

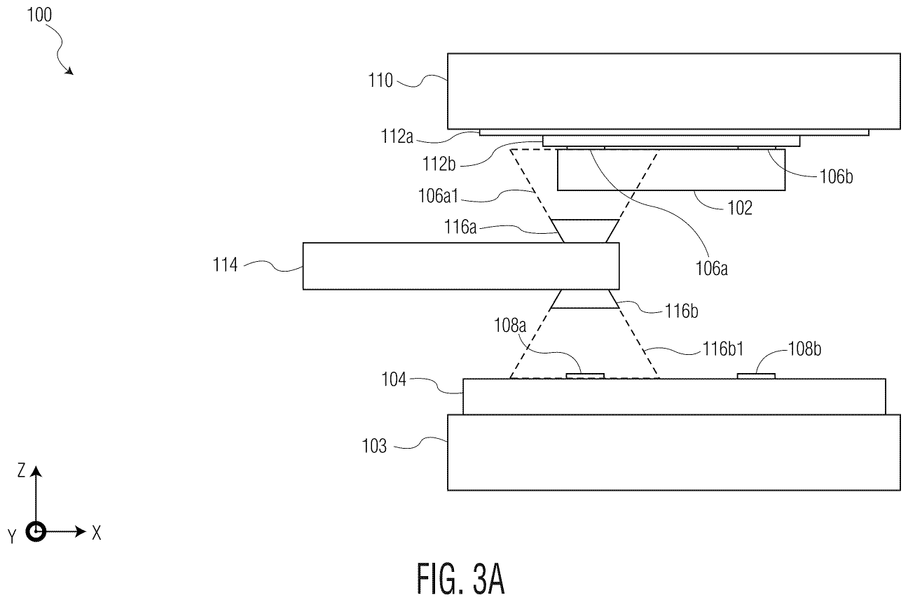

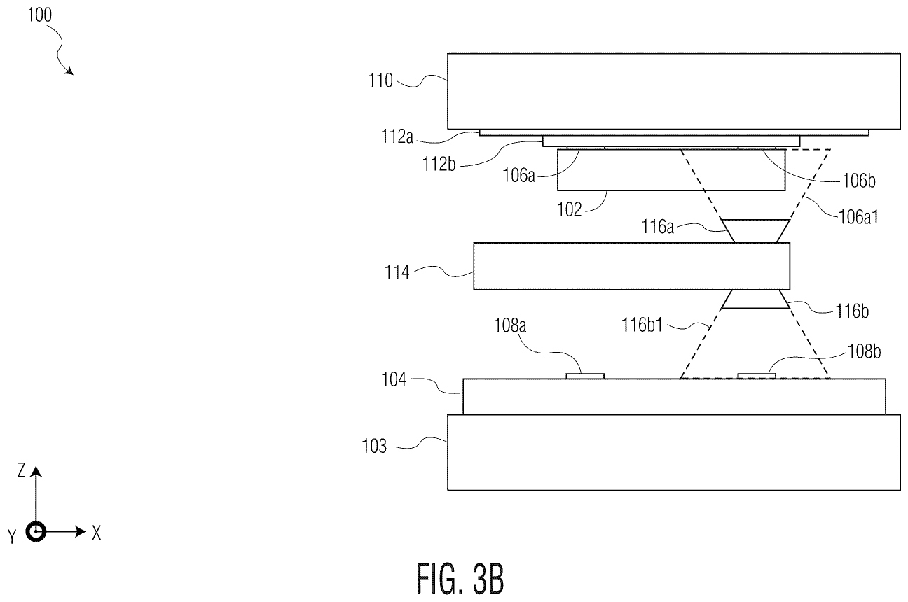

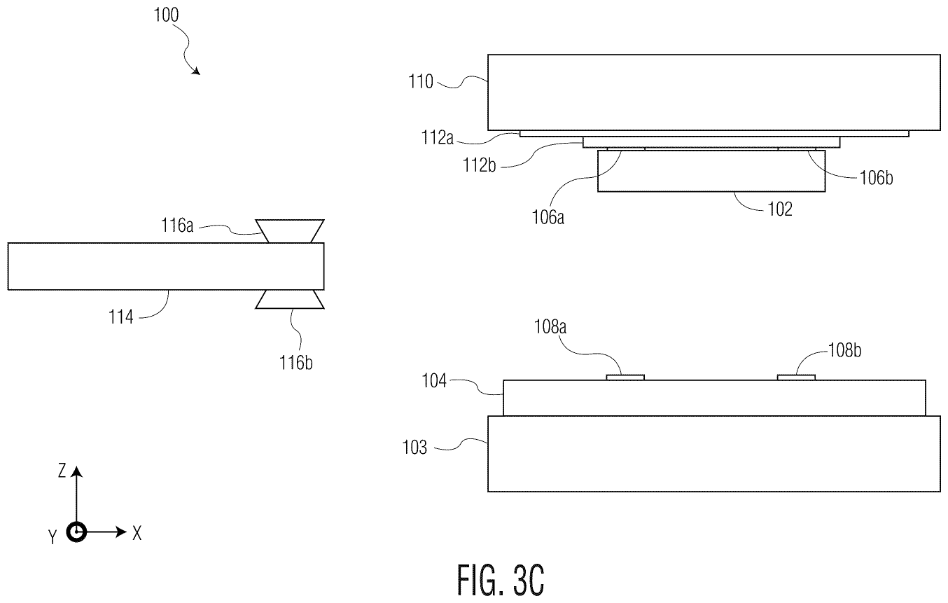

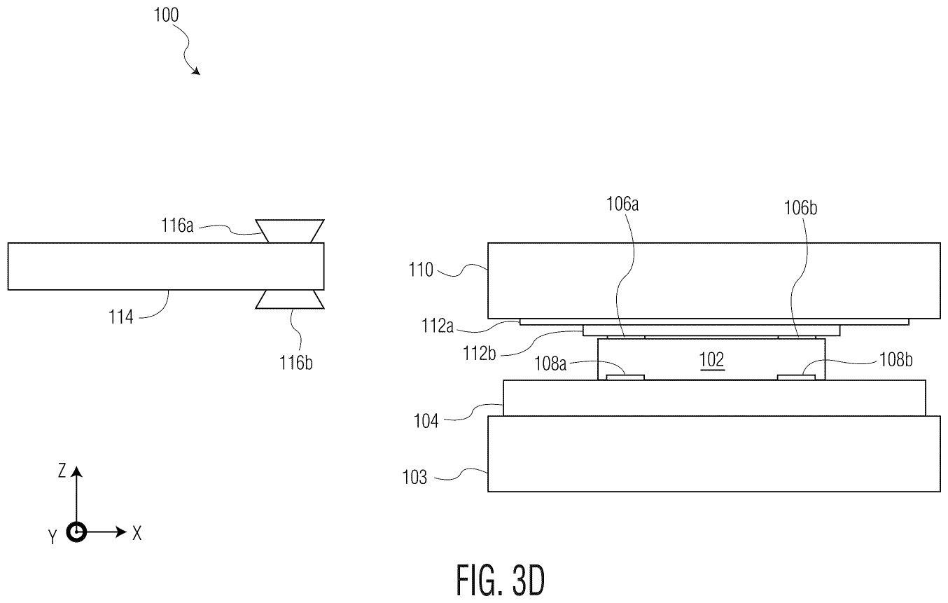

While FIGS. 2A-2F illustrate a sequential imaging of fiducial markings (e.g., first imaging the fiducial markings on substrate 104, and then imaging the fiducial markings on semiconductor element 102), the invention is not limited thereto. For example, in certain applications, it may be desirable to image fiducial markings of a substrate at the same time as imaging the fiducial markings on a semiconductor element. FIGS. 3A-3D is an example of such an application. For example, the imaging system may be configured to image one of the fiducial markings on the upper surface of the substrate simultaneously with imaging one of the fiducial markings on the semiconductor element.

FIG. 3A illustrates imaging system 114 using visible light 116b1 (from look down imaging path 116b) in connection with imaging of fiducial marking 108a on substrate 104 simultaneously with using light having an infrared wavelength 116a1 (from look up imaging path 116a) in connection with imaging of fiducial marking 106a on semiconductor element 102. Then, FIG. 3B illustrates imaging system 114 using visible light 116b1 (from look down imaging path 116b) in connection with imaging of fiducial marking 108b on substrate 104 simultaneously with using light having an infrared wavelength 116a1 (from look up imaging path 116a) in connection with imaging of fiducial marking 106b on semiconductor element 102.

After the imaging operations shown in FIGS. 3A-3B are completed (e.g., imaging operations with respect to fiducial markings 106a and 106b on the semiconductor element 102, and with respect to fiducial markings 108a and 108b on substrate 104), imaging system 114 is moved as shown in FIG. 3C, such that there is a clear path for bonding tool 112b to bond semiconductor element 102 to substrate 104. With data from the imaging operations of imaging system 114, calculations are completed for corrections to be made to properly align semiconductor element 102 with substrate 104 (e.g., corrections along the x-axis, corrections along the y-axis, corrections about the z-axis, etc.). Using these corrections, semiconductor element 102 is then properly aligned with substrate 104 (e.g., through motion of bond head assembly 110 and/or support structure 103). Then, after the alignment is completed, semiconductor element 102 is bonded (e.g., thermocompressively bonded) to substrate 104 at FIG. 3D.

Aspects of the invention provide significant advantages over conventional bonding systems and methods. For example, in certain conventional systems, a semiconductor element (including fiducial markings on the top side) is imaged prior to pick up by the bonding tool. Thus, alignment is considered complete prior to pick up by the bonding tool. Thus, additional positional error exists in connection with this pick up operation. Aspects of the invention avoid this problem by imaging the top side fiducial markings on the semiconductor element after the semiconductor element has been picked up by the bonding tool.

Although the invention has been illustrated and described primarily with respect to a semiconductor element having two fiducial markings, and a target substrate having two fiducial markings, the invention is not limited thereto. Aspects of the invention are applicable to a semiconductor element (and/or a target substrate) having at least one fiducial marking and/or a semiconductor element (and/or a target substrate) having a plurality of fiducial markings.

Although the invention is illustrated and described herein with reference to specific embodiments, the invention is not intended to be limited to the details shown. Rather, various modifications may be made in the details within the scope and range of equivalents of the claims and without departing from the invention.

What is claimed:

1. A bonding system for bonding a semiconductor element to a substrate, the bonding system comprising:
a bonding tool configured for bonding the semiconductor element to the substrate, the bonding tool configured to carry the semiconductor element with at least one fiducial marking on the semiconductor element facing the bonding tool; and
an imaging system for imaging the at least one fiducial marking from a position beneath the semiconductor element while the semiconductor element is being carried by the bonding tool.

2. The bonding system of claim 1 wherein the bonding system is a thermocompression bonding system.

3. The bonding system of claim 1 wherein the imaging system is configured to use light having an infrared wavelength in connection with the imaging of the at least one fiducial marking on the semiconductor element.

4. The bonding system of claim 1 further comprising a support structure configured for supporting the substrate with at least one fiducial marking on an upper surface of the substrate.

5. The bonding system of claim 4 wherein the imaging system is configured to use visible light in connection with imaging of the at least one fiducial marking on the substrate.

6. The bonding system of claim 1 further comprising a support structure configured for supporting the substrate with at least one fiducial marking on an upper surface of the substrate, wherein the imaging system is configured to use light having an infrared wavelength in connection with the imaging of the at least one fiducial marking on the semiconductor element, and wherein the imaging system is configured to use visible light in connection with imaging of the at least one fiducial marking on the substrate.

7. The bonding system of claim 6 wherein the imaging system is a look up/down imaging system, the imaging system utilizing a look up imaging path for imaging the at least one fiducial marking on the semiconductor element, the imaging system utilizing a look down imaging path for imaging the at least one fiducial marking on the substrate.

8. The bonding system of claim 1 further comprising a support structure configured for supporting the substrate with a plurality of fiducial markings on an upper surface of the substrate, wherein the at least one fiducial marking on the semiconductor element includes a plurality of fiducial markings on the semiconductor element, wherein the imaging system is configured to image one of the fiducial markings on the upper surface of the substrate simultaneously with imaging of one of the fiducial markings on the semiconductor element.

9. The bonding system of claim 1 wherein the bonding system is configured to align the semiconductor element with the substrate after imaging of the at least one fiducial marking on the semiconductor element.

10. The bonding system of claim 1 further comprising a support structure configured for supporting the substrate with at least one fiducial marking on an upper surface of the substrate, the imaging system being configured to image the at least one fiducial marking on the upper surface of the substrate, wherein the bonding system is configured to align the semiconductor element with the substrate after imaging of (i) the at least one fiducial marking on the semiconductor element and (ii) the at least one fiducial marking on the upper surface of the substrate.

11. A method of bonding a semiconductor element to a substrate, the method comprising the steps of:
(a) carrying the semiconductor element with a bonding tool with at least one fiducial marking on the semiconductor element facing the bonding tool;
(b) imaging the at least one fiducial marking with an imaging system from a position beneath the semiconductor element while the semiconductor element is being carried by the bonding tool; and
(c) bonding the semiconductor element to the substrate.

12. The method of claim 11 wherein step (c) includes thermocompressively bonding the semiconductor element to the substrate.

13. The method of claim 11 wherein step (b) includes using light having an infrared wavelength in connection with the imaging of the at least one fiducial marking on the semiconductor element.

14. The method of claim 11 further comprising a step of supporting the substrate with a support structure, the support structure being configured to support the substrate with at least one fiducial marking on an upper surface of the substrate.

15. The method of claim 14 further comprising a step of using visible light in connection with imaging of the at least one fiducial marking on the substrate.

16. The method of claim 11 further comprising a step of supporting the substrate with a support structure, the support structure being configured to support the substrate with at least one fiducial marking on an upper surface of the substrate,
wherein step (b) includes using light having an infrared wavelength in connection with the imaging of the at least one fiducial marking on the semiconductor element,
further comprising a step of using visible light from the imaging system in connection with imaging of the at least one fiducial marking on the substrate.

17. The method of claim 16 wherein the imaging system is a look up/down imaging system, the imaging system utilizing a look up imaging path for imaging the at least one fiducial marking on the semiconductor element, the imaging system utilizing a look down imaging path for imaging the at least one fiducial marking on the substrate.

18. The method of claim 11 further comprising a step of supporting the substrate with a support structure, the support structure being configured to support the substrate with a plurality of fiducial markings on an upper surface of the substrate,
wherein the at least one fiducial marking on the semiconductor element includes a plurality of fiducial markings on the semiconductor element,
wherein step (b) includes using the imaging system to image one of the fiducial markings on the upper surface of the substrate simultaneously with imaging of one of the fiducial markings on the semiconductor element.

19. The method of claim 11 further comprising a step of aligning the semiconductor element with the substrate after step (b).

20. The method of claim 11 further comprising a step of supporting the substrate with a support structure, the support structure being configured to support the substrate with at least one fiducial marking on an upper surface of the substrate,
further comprising a step of imaging the at least one fiducial marking on the upper surface of the substrate with the imaging system,
further comprising a step of aligning the semiconductor element with the substrate before step (c), after step (b), and after the step of imaging the at least one fiducial marking on the upper surface of the substrate with the imaging system.
